(19) United States
(12) Patent Application Publication
(10) Pub. No.: US 2008/0191920 A1
(43) Pub. Date: Aug. 14, 2008

(54) Low-voltage drop reference generation circuit for A/D converter

(76) Inventor: Sangbeom Park, San Jose, CA (US)

Correspondence Address: Kieun Park, DBA ANA Semiconductor, P.O. Box 65, Tracy, CA, 95376, US

(21) Appl. No.: 11/705,998

(22) Filed: Feb. 12, 2007

(51) Int. Cl. H03M 1/34

(52) U.S. Cl. 341/158

(57) ABSTRACT

Two cost-effective low-voltage drop reference generation circuits for A/D converter of the present invention generates a plurality of reference voltages characterized by voltage increments between two fixed reference voltages, which are able to be close to positive rail and negative rail (or ground). These low-voltage drop generation circuits not only greatly increases the total reference voltage range (i.e., increases voltage difference between the most positive reference voltage and the most negative reference voltage, increases V_{REFT}−V_{REFB}, maximizes the most positive reference voltage and minimizes the most negative reference voltage), but also enables A/D converter to convert rail-to-rail analog input with maintaining good power supply rejection with respect to positive power and negative power (or ground).

### FIELD OF THE INVENTION

The present invention relates to the field of analog-to-digital converters and more particularly to low-voltage drop reference generation circuit for A/D converters basically utilizing a resistor string, two transistors, and two amplifiers.

### BACKGROUND ART

In interfacing between the analog and digital domain, the analog-to-digital (A/D) converter is a vitally important device. The A/D converter converts an analog signal such as a voltage or a current into a digital signal, which can be further processed, stored, and disseminated using digital processors. For example, A/D converters are used in communications, appliances, display, signal processing, computers, medical instrumentation, industries, and any other fields that require conversion of analog signals into digital forms.

The A/D converter encodes an analog input signal into a digital output signal of a predetermined bit length. The A/D converter basically includes a resistor string which is comprised of a plurality of resistors. The resistors form a resistor string and are coupled in series between two reference voltages: the most positive reference voltage and the most negative reference voltage. These reference voltages are then fed into several blocks such as comparators, digital-to-analog (D/A) subsection, preamplifiers, and interstage amplifiers.

Prior Art FIG. 1 illustrates a circuit diagram of a conventional reference generation circuit for A/D converter 100. The conventional reference generation circuit for A/D converter shown in Prior Art FIG. 1 is comprised of a plurality of resistors and an amplifier 121. The resistors form a resistor string and are coupled in series between two reference voltages: the most positive reference voltage, V_{REFT}, and the most negative reference voltage, V_{REFB}. It is noted that the negative input of the amplifier 121 is connected to its output node. Thus, it becomes voltage-follower configuration. This conventional circuit 100 generates a plurality of reference voltages characterized by voltage increments between the most positive reference voltage, V_{REFT}, and the most negative reference voltage, V_{REFB}.

Unfortunately, the conventional reference generation circuit for A/D converter 100 is inefficient to implement in integrated circuit (IC) chip. First, the power supply rejection with respect to negative power supply (or ground) rather than positive power supply is significantly degraded at node 104. In reality, switches and analog blocks are connected to the nodes between the serially coupled resistors in Prior Art FIG. 1. The regulation at the node 104 is much weaker than in the case of the node 101 whenever charge-injection error occurs at the node (i.e., whenever MOS switches (not shown), which connected to the nodes between the serially coupled resistors, turn off). Furthermore, voltage at the node 101 (i.e., V_{REFT}) becomes V_{REFTIN} for V_{DROPB}<V_{REFIN}<V_{DD}−V_{DROPT}. Thus, voltage drop between power supply and the most positive reference voltage (i.e., V_{DD}−V_{REFT}) is usually lager than average MOS device threshold voltage (i.e., thick oxide MOS device threshold voltage). Thus, the conventional reference generation circuit for A/D converter 100 has a major limitation on rail-to-rail A/D converters and will miss codes for large-swing analog input signal, as shown in Prior Art FIG. 1. Thus, minimum performance of rail-to-rail A/D converters can not be achieved without low-voltage drop reference generation circuit for all types of A/D converters.

Thus, what is needed is cost-effective low-voltage drop reference generation circuits for A/D converter that can be easily designed and efficiently implemented along with maximizing the total reference voltage range and power supply rejection with respect to both positive power supply and negative power supply (or ground). The present invention satisfies these needs by providing two low-voltage drop reference generation circuits for A/D converter basically utilizing a resistor string, two transistors, and two amplifiers.

### SUMMARY OF THE INVENTION

The present invention provides two cost-effective low-voltage drop reference generation circuits for A/D converter. The cost-effective low-voltage drop reference generation circuits for A/D converter of the present invention basically includes a resistor string, two transistors, two amplifiers (or operational amplifiers). The resistor string generates a plurality of reference voltages characterized by voltage increments between two fixed reference voltages. In this configuration, the two transistors are used as common-source amplifier and each amplifier receives a reference voltage at its negative input. The generated reference voltages are not only constant with respect to the fluctuations of positive power supply and negative power supply (or ground), but also greatly increases the total reference voltage range (i.e., increases voltage difference between the most positive reference voltage and the most negative reference voltage, increases V_{REFT}−V_{REFB}, maximizes the most positive reference voltage and minimizes the most negative reference voltage). The present invention achieves a drastic improvement in increasing the total reference voltage range with good power supply rejection with respect to positive power supply and negative power supply (or ground).

### BRIEF DESCRIPTION OF THE DRAWINGS

The accompanying drawings, which are incorporated in and form a part of this specification, illustrate embodiments of the invention and, together with the description, serve to explain the principles of the invention:

Prior Art FIG. 1 illustrates a circuit diagram of a conventional reference generation circuit for A/D converter.

FIG. 2 illustrates a circuit diagram of a low-voltage drop reference generation circuit for A/D converter in accordance with the present invention.

FIG. 3 illustrates a circuit diagram of a flexible low-voltage drop reference generation circuit for A/D converter according to the present invention.

### DESCRIPTION OF THE PREFERRED EMBODIMENTS

In the following detailed description of the present invention, two cost-effective low-voltage drop reference generation circuits for A/D converter, numerous specific details are set forth in order to provide a through understanding of the present invention. However, it will be obvious to one skilled in the art that the present invention may be practiced without these specific details. In other instances, well known methods, procedures, components, and circuits have not been described in detail so as not to unnecessarily obscure aspects of the present invention.

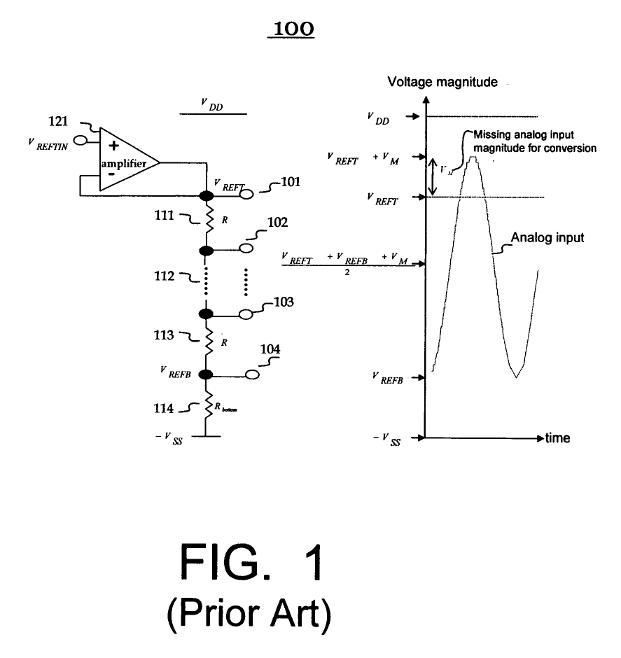

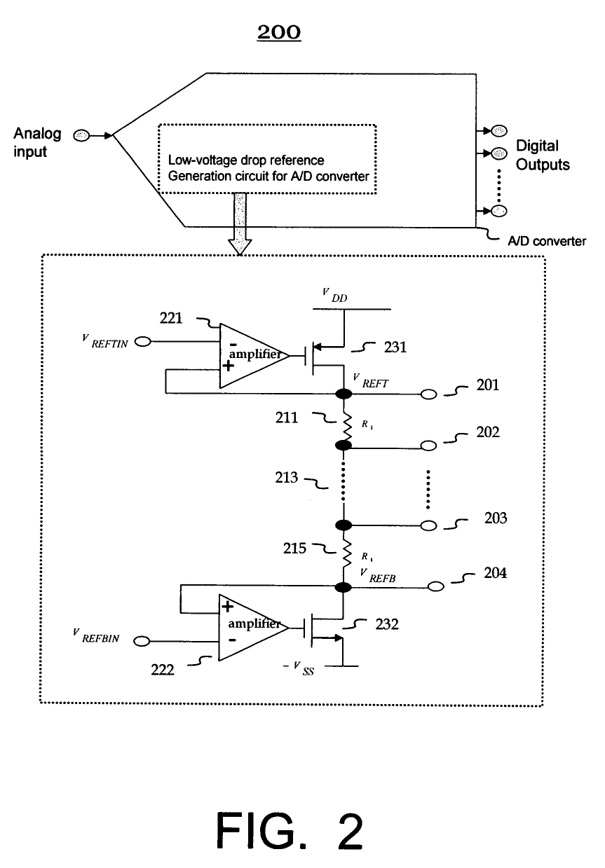

FIG. 2 illustrates a low-voltage drop reference generation circuit for A/D converter in accordance with the present invention. The low-voltage drop reference generation circuit for A/D converter 200 is comprised of n resistors, a PMOS transistor 231, an NMOS transistor 232, and two amplifiers (or operational amplifiers) 221 and 222. The amplifiers 221 and 222 are termed upper amplifier and lower amplifier, respectively. The resistor string generates n−1 spaced reference voltages between two reference voltages such as V_{REFT} and V_{REFB}. The dotted lines 213 represent m resistors where m is an integer greater than or equal to one. As shown in FIG. 2, the two transistors are used as common-source amplifier and each amplifier (or operational amplifier) receives a reference voltage at its negative input. It is noted that the positive input of the amplifier 221 is connected to the drain node of the PMOS transistor 231 and its output is connected to the gate node of the PMOS transistor 231. The amplifier 221 and PMOS transistor 231 are in negative feedback configuration. Likewise, the amplifier 222 and NMOS transistor 232 are in negative feedback configuration. Even though V_{REFTIN} goes up close to positive power supply, voltage at a node 201 (i.e., V_{REFT}) still becomes equal to V_{REFTIN}. Even though V_{REFBIN} goes down close to negative power supply (or ground), voltage at a node 204 (i.e., V_{REFB}) still becomes equal to V_{REFBIN}. In addition, as voltages at both positive power supply and negative power supply (or ground) change, the voltage at the node 204 will be much more constant than the case of Prior Art FIG. 1 (i.e., the voltage at the node 104). However, the regulation at all nodes 201 through 204 shown in FIG. 2 is much stronger than in the case of Prior Art FIG. 1 whenever charge-injection error occurs at the nodes (i.e., whenever MOS switches (not shown), which connected to the nodes between the serially coupled resistors, turn off). Thus, the low-voltage drop reference generation circuit for A/D converter 200 provides a strong basis for all types of rail-to-rail A/D converters, and can be efficiently implemented along with increasing the total reference voltage range and maintaining good power supply rejection with respect to both positive power supply and negative power supply (or ground). The present invention generates low-voltage drop reference voltages utilizing a resistor string, two amplifiers (or operational amplifiers), and two transistors. Amplifiers are well known circuits in the art and can be implemented using various well known devices such as transistors, capacitors, resistors, etc. In addition, the amplifiers (or operational amplifiers) 221 and 222 are differential-input single-ended output amplifiers and can have any number of gain stages with or without buffer stage (i.e., output stage).

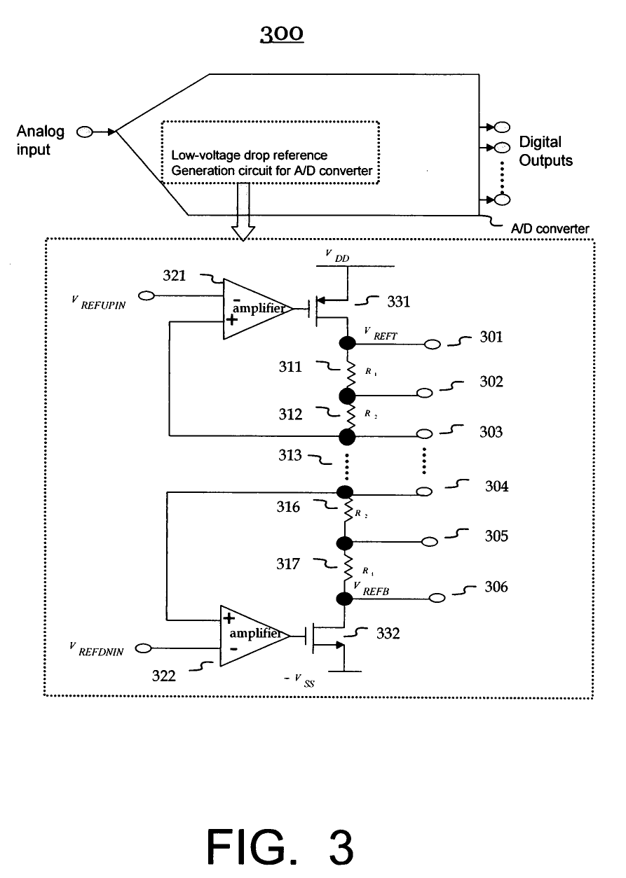

FIG. 3 illustrates a circuit diagram of a flexible low-voltage drop reference generation circuit for A/D converter 300 according to the present invention. The flexible low-voltage drop reference generation circuit for A/D converter 300 is comprised of n resistors, a PMOS transistor 331, an NMOS transistor 332, two amplifiers (or operational amplifiers) 321 and 322. The amplifiers 321 and 322 are termed upper amplifier and lower amplifier, respectively. The dotted lines 313 represent m resistors where m is an integer greater than or equal to one. The resistor string consists of an upper part 311 and 312, a middle part 313, and a lower part 316 and 317. However, the middle part of the resistor string is excluded in either feedback loop.

In addition, it is also noted that the amplifier 321, PMOS transistor 331, and resistors 311 and 312 shown in FIG. 3 are in negative feedback configuration in the same fashion as the amplifier 221 and PMOS transistor 231. However, a difference between FIG. 2 and FIG. 3 is that upper part 311 and 312 and lower part 316 and 317 shown in FIG. 3 are included in each feedback path. Thus, even though V_{REFUPIN} is not close to V_{DD} and V_{REFDNIN} is not close to −V_{SS} (or ground), voltage at node 301 (i.e., V_{REFT}, the most positive reference voltage) and voltage at node 306 (i.e., V_{REFB}, the most negative reference voltage) become a constant reference voltage closed to V_{DD} and a constant reference voltage closed to −V_{SS} (or ground), respectively. The flexible low-voltage drop reference generation circuit for A/D converter 300 is highly effective when V_{REFUPIN} is not high enough and V_{REFDNIN} is not low enough.

In summary, the low-voltage drop reference generation circuit for A/D converter 200 and the flexible low-voltage drop reference generation circuit for A/D converter 300 can also be implemented using additional capacitors attached to the nodes 201 through 204 and the nodes 301 through 306, respectively. In addition, the two low-voltage drop reference generation circuits of the present invention are highly efficient to implement in integrated circuit (IC) and system-on-chip (SOC). The low-voltage drop reference generation circuit for A/D converter 200 of the present invention achieves a drastic improvement in the total reference voltage range and converting larger analog signal swing and power supply rejection. In addition to the strengths mentioned above, the flexible low-voltage drop reference generation circuit for A/D converter 300 of the present invention provides the most positive reference voltage higher than V_{REFUPIN} and the most negative reference voltage lower V_{REFDNIN} when high V_{REFUPIN} and low V_{REFDNIN} are not available. While the present invention has been described in particular embodiments, it should be appreciated that the present invention should not be construed as being limited by such embodiments, but rather construed according to the claims below.

What is claimed is:

1. A low-voltage drop reference generation circuit for A/D converter for generating reference voltages for A/D conversion, comprising:
a resistor string for generating a plurality of reference voltages wherein the n resistors are coupled in series between two fixed reference voltages where n is an integer;
a PMOS transistor and an NMOS transistor for causing phase inversion wherein the PMOS transistor is coupled between the most positive node of the resistor string and positive power supply and the NMOS transistor is coupled between the most negative node of the resistor string and negative power supply;
an upper amplifier and a lower amplifier for making their positive input and negative input equal wherein each negative input receives a reference voltage and each positive input is coupled to a node between resistors that form the resistor string;
an upper part of the resistor string coupled between the upper amplifier's positive input and the drain node of the PNOS transistor wherein the upper part of the resistor string, the upper amplifier, and the PNOS transistor form first feedback configuration;
a lower part of the resistor string coupled between the lower amplifier's positive input and the drain node of the NNOS transistor wherein the lower part of the resistor string, the lower amplifier, and the NNOS transistor form second feedback configuration; and
a middle part of the resistor string coupled between two positive inputs of the amplifiers wherein the middle part of the resistor string is outside either feedback configuration.

2. The circuit as recited in claim 1 wherein the upper part of the resistor string does not include any resistor.

3. The circuit as recited in claim 1 wherein the upper part of the resistor string comprises at least a resistor.

4. The circuit as recited in claim 1 wherein the middle part of the resistor string comprises at least a resistor.

5. The circuit as recited in claim 1 wherein the lower part of the resistor string does not include any resistor.

6. The circuit as recited in claim 1 wherein the lower part of the resistor string comprises at least a resistor.

7. The circuit as recited in claim 1 wherein the amplifiers are differential-input single-ended output amplifiers.

8. The circuit as recited in claim 1 wherein the amplifiers are differential-input single-ended output operational amplifiers.

9. The circuit as recited in claim 1 wherein power-down transistors can be added to a node between the serially coupled resistors so that the node is at ground during power-down mode.

10. The circuit as recited in claim 12 wherein a capacitor can be coupled between the output node of the upper amplifier and the most positive node of the resistor string.

11. The circuit as recited in claim 12 wherein a capacitor can be coupled between the output node of the lower amplifier and the most negative node of the resistor string.

12. The circuit as recited in claim 12 wherein a resistor and a capacitor connected in series can be coupled between the output node of the upper amplifier and the most positive node of the resistor string.

13. The circuit as recited in claim 12 wherein a resistor and a capacitor connected in series can be coupled between the output node of the lower amplifier and the most negative node of the resistor string.

14. The circuit as recited in claim 1 wherein capacitors can be added to the output nodes of the two amplifiers, the two fixed reference voltages, and the nodes between the serially coupled resistors.

15. The circuit as recited in claim 1 wherein the negative power supply is negative power supply.

16. The circuit as recited in claim 1 wherein the negative power supply is ground.

17. The circuit as recited in claim 1 wherein the resistor string is unfolded resistor string.

18. The circuit as recited in claim 1 wherein the resistor string is multiple time-folded resistor string.

19. The circuit as recited in claim 1 wherein the top resistor and the bottom resistor of the resistor string have the same resistance.

20. The circuit as recited in claim 1 wherein the low-voltage drop reference generation circuit is developed for use in all types of A/D converters without regard to architectures, types, topologies, and schematics.
